(19) United States
(12) Patent Application Publication
(10) Pub. No.: US 2015/0049883 A1
(43) Pub. Date: Feb. 19, 2015

(54) AMPLIFIER

(71) Applicant: MI AUDIO PTY LIMITED, Sydney, New South Wales (AU)

(72) Inventor: Michael Ibrahim, Newtown (AU)

(21) Appl. No.: 14/386,205

(22) PCT Filed: Mar. 19, 2013
(86) PCT No.: PCT/AU2013/000272

§ 371 Date: Sep. 18, 2014

(30) Foreign Application Priority Data
Mar. 20, 2012 (AU) 2012901122

(51) Int. Cl. H03F 3/181

(52) U.S. Cl. CPC H03F 3/181
USPC 381/118

(57) ABSTRACT

An amplifier, such as a vacuum tube guitar amplifier, including a configurable preamplifier, power amplifier and/or power supply. Configuration of sections of the amplifier can be controlled by software, which can be updated directly on the amplifier though an editing interface, by downloading new configuration data from an external device or network, or by updating hardware-based cards or daughter-boards. The amplifier can store multiple circuit designs, and give users access to designs on demand, along with associated potentiometer and switch settings stored in ‘patches’, as well as allow real-time control over potentiometer settings via the amplifier's user interface, or external control via a communications interface. Global settings can also be configured to take into account factors such as type and rating of vacuum tubes. The same methodology can be applied to stand-alone preamplifiers or power amplifiers, solid state amplifiers, preamplifiers or power amplifiers.

### TECHNICAL FIELD

The present invention generally relates to amplifiers, and in preferred forms to guitar amplifiers. In particular example forms, the present invention relates to a vacuum tube amplifier, a solid state amplifier and/or a hybrid amplifier having both vacuum tube and solid state components. In further particular example forms, the present invention relates to configurable vacuum tube, solid state and/or hybrid preamplifiers, tone controls, power amplifiers and/or power supplies.

### COPYRIGHT NOTICE/PERMISSION

A portion of the disclosure of this patent specification contains material that is subject to copyright protection. The copyright owner has no objection to the facsimile reproduction by anyone of the patent specification or parts thereof as it appears in the file or records of a Patent Office, but otherwise reserves all copyrights whatsoever.

### BACKGROUND

The electric guitar is undoubtedly one of the most prominent instruments in modern music. The advent of audio amplification in the early part of the 20^{th} century allowed musicians to circumvent some of the shortcomings of acoustic instruments. This in turn fed into the continued evolution of the design of musical instruments, for which acoustic performance was no longer the primary design criterion. The electric guitar is a perfect example of this phenomenon.

The general perception of the vast majority of people is that the ‘tools of the trade’ of a typical musician can be classified into two groups: the instruments directly used by the musician to create music, and other equipment which are much more utilitarian in nature. In the example of the electric guitarist, the guitar itself is the instrument, whilst everything else (effects, amplifiers, etc.) constitutes the guitarist's equipment. In reality, this distinction is not a valid one for the electric guitar. To understand this, it should be noted that broadly speaking, the sound and tonal characteristics of all electric guitars are, in the grand scheme of things, relatively uniform. Various guitar designs do not account for the large variety of sounds and musical styles for which electric guitars are utilised. For example, if two vastly ‘different’ electric guitars are plugged into the same set of effects and amplifier, the resultant tone and musical timbre would not change dramatically. However, the converse it not true. The same electric guitar plugged into a different set of effects and amplifiers would sound radically different. Thus, the so-called ‘equipment’ used with electric guitars form a pivotal part of the expressiveness of the instrument itself. In reality, the equipment should in fact be considered an extension of the instrument.

There are a few interesting points to note about the role of the guitar amplifier.

Firstly, the 1950's to 1970's saw an explosion in the popularity of music dependent on electric instruments, most notably the electric guitar. The most common, if not exclusive, technology utilised in amplification at the time was vacuum tube (i.e. valve) circuitry. In the 1970's as solid state technology became more readily available and economically viable, amplifier manufacturers began to phase out vacuum tube designs in favour of the more reliable, cheaper and ‘superior’ designs based on solid state devices. However, the historical congruence of vacuum tube amplifiers and ‘seminal’ popular music, coupled with the surprisingly conservative attitude of electric guitarists meant that the tone of vacuum tube amplifiers was always considered superior.

Secondly, the tonal characteristics of vacuum tube amplifiers which guitarists considered to be desirable was in some ways accidental, and came about as a result of guitarists utilising amplifiers in ways which the designers did not intend, most notably under overdrive conditions. Under these conditions, the amplification system exhibited non-linear behaviour, not only in response of the vacuum tubes, but also the output transformer and speakers, not to mention the dynamic response of the amplifier's power supply. Rather interestingly, it took some time for amplifier manufacturers to appreciate the fact that electric guitarists sought out this behaviour in their amplifiers. Many amplifier manufacturers actively sought out ways to reduce these properties of their amplifiers, assuming they were ‘undesirable’. For example, many early amplifiers included a low sensitivity input, with the assumption that guitarists would plug their guitars into this input if the amplified signal was too distorted.

The reality of the situation was the opposite, namely that guitarists were often looking for ways to increase the distortion of their amplifiers. This involved such techniques as utilising external preamplifier units between the guitar and amplifier to boost or distort the signal before the signal reached the input of the amplifier, or in more extreme cases, the modification of the amplifier's circuit to increase the signal gain and distortion.

Eventually amplifier manufacturers began to respond to the needs of guitarists, and began to build amplifiers with more inbuilt distortion. Because of the nature of vacuum tubes, this often involved the addition of further preamplifier gain stages. At the same time amplifier designers began to shift the ‘location’ of the distortion from the power amplifier and output stage to the preamplifier circuitry. This had the advantage of creating a distorted sound at any volume.

Another aspect of the evolution of the modern vacuum tube guitar amplifier was the introduction of different preamplifier circuits in the same amplifier unit. This increased the flexibility of amplifiers, since the guitarist now had access to different timbres, with varying levels of distortion and frequency responses. These were eventually coupled with foot-switching controllers, so that guitarists could access these different preamplifier circuits in a live situation. As guitar amplifier design became more complex, more preamplifier ‘channels’ were added, and in some cases, switching channels also involved the switching of some aspects of the power amplifier circuitry, in order to further modify the diversity of tones available. Finally, in order to facilitate the integration of these amplifiers into modern equipment setups, the most advanced vacuum tube amplifiers included rudimentary digital control systems which allowed the amplifiers' basic functions to be controlled via the MIDI (Musical Instrument Digital Interface) standard. To date, this is the limit of complexity of vacuum tube guitar amplifiers.

In parallel to these developments, different approaches were taken by various equipment designers to fulfil the sonic requirements of guitarists without having to completely resort to vacuum tube circuitry.

The first of these approaches, as touched upon previously, was the use of solid state circuitry. Initially, these designs were developed independently of vacuum tube designs, and were poorly received by many guitarists due to the very different characteristics of these circuits when compared to the favoured benchmark sounds of vacuum tube amplifiers. Accordingly many designers sought ways of approximating the characteristics of vacuum tube circuits using solid state approximations, to varying degrees of success. Finally, some designs involved creating hybrid systems, incorporating predominantly solid-state circuitry, but with the addition of vacuum tube components in sections which the designers felt were significant.

The second of these approaches involved Digital Signal Processing (DSP). Initially, the use of digital technology in guitar related equipment was centred on the use of DSP in audio effects, such as reverb, echo and modulation, since these were more difficult to achieve using analog technology. Rudimentary ‘overdrive’ and ‘distortion’ sounds were also developed. As the processing power of DSPs increased, it became possible to implement more complex processing algorithms which utilised circuit-level simulation of vacuum tube amplifier circuits. This technique, commonly referred to as ‘Digital Modelling’ has now become a very popular technology ‘genre’. A related, though different technique of ‘modelling’ involves the analysis of impulse responses of guitar amplifiers, commonly referred to as ‘Profiling’. Though different, this ultimately is also another technique which uses DSP to approximate the sound of vacuum tube guitar amplifiers.

Though DSP modelling is now a powerful force in the guitar equipment industry, there is no doubting that vacuum tube circuitry still remains the tonal benchmark for guitar amplification. However, in many respects, DSP systems exhibit a clear superiority over traditional analog guitar amplifiers, including vacuum tube, solid state, and hybrid designs. The most prominent of these include:
Flexibility: whilst a typical analog guitar amplifier may offer a small rage of circuits, it is possible for digital modellers to offer hundreds of amplifier simulations in the one unit, negating the need for a guitarist to own hundreds of different amplifiers to create a similar range of tones.
Programmability: whilst all but a small number of analog guitar amplifiers have only one setting per ‘channel’ adjusted via the control potentiometers, most digital modellers allow the user to store up to hundreds of settings with various virtual potentiometer settings.
Updatability: a digital modeller will typically allow the user to download and update new patches, and new circuit simulations, so that the guitarist can constantly update their foundational tone.

To date, it has not been possible for traditional analog amplifiers and preamplifiers, whether vacuum tube, solid state or hybrid, to feature such flexibility, programmability and updatability. Although guitar amplifiers have been discussed in detail, it should be noted that similar issues or problems can apply to amplification for other musical instruments or equipment.

There is a need for a new or improved amplifier, and/or components thereof such as a preamplifier, a power amplifier and/or a power supply, which address or at least ameliorate one or more problems inherent in the prior art.

The reference in this specification to any prior publication (or information derived from the prior publication), or to any matter which is known, is not, and should not be taken as an acknowledgment or admission or any form of suggestion that the prior publication (or information derived from the prior publication) or known matter forms part of the common general knowledge in the field of endeavour to which this specification relates.

### SUMMARY

This summary is provided to introduce a selection of concepts in a simplified form that are further described below in the preferred embodiments. This summary is not intended to identify key features or essential features of the claimed subject matter, nor is it intended to be used to limit the scope of the claimed subject matter.

In a broad form the present invention provides a new amplifier, or components thereof. Preferably, though not necessarily, the amplifier is a guitar amplifier. In particular example forms, there is provided a vacuum tube amplifier, a solid state amplifier and/or a hybrid amplifier having both vacuum tube and solid state components. In further particular example forms, there is provided a vacuum tube, solid state and/or hybrid preamplifier. In still further particular example forms, there is provided a vacuum tube, solid state and/or hybrid power amplifier. Preferably, though not necessarily, the preamplifier is a guitar preamplifier and the power amplifier is a guitar power amplifier. The amplifier, preamplifier, power amplifier and/or a power supply can be used with signals or sound generated from a wide variety of other sources, such as other musical instruments.

According to a first example form, there is provided an amplifier comprising: a plurality of gain stages; and, a bypass switch operable to switch in or out of operation a gain stage of the plurality of gain stages.

According to a second example form, there is provided a guitar amplifier, comprising: a vacuum tube including an anode and a cathode; and, a configurable electrical component connected to the vacuum tube.

In other particular, but non-limiting, forms: at least one of the plurality of gain stages is a vacuum tube gain stage; there is a plurality of bypass switches each associated with a different gain stage of the plurality of gain stages; and/or each bypass switch of the plurality of bypass switches is operable to switch in or out of operation the associated different gain stage of the plurality of gain stages.

In another example form, there are included tone controls and at least one tone controls bypass switch to control the electrical connection of the tone controls with respect to the plurality of gain stages.

Optionally, the amplifier is a guitar amplifier, a preamplifier, or a power amplifier.

In a further particular, but non-limiting, form the at least one tone controls bypass switch is operable to electrically connect the tone controls to or near to a first gain stage, or alternatively to electrically connect the tone controls to or near to a last gain stage.

In other particular, but non-limiting, forms: the first gain stage is electrically positioned before the at least one tone controls bypass switch; and/or the first gain stage is electrically positioned before the bypass switch.

In still further particular, but non-limiting, forms: the configurable electrical component is a configurable resistance component, a configurable capacitance component and/or a configurable inductance component; the configurable electrical component includes one or more variable resistors; the configurable electrical component includes a resistor connected in series to a switch to provide a switchable resistor, and a plurality of switchable resistors electrically arranged in parallel; the configurable electrical component includes a resistor connected in parallel to a switch to provide a switchable resistor, and a plurality of switchable resistors electrically arranged in series; the configurable electrical component includes one or more variable capacitors; the configurable electrical component includes a capacitor connected in series to a switch to provide a switchable capacitor, and a plurality of switchable capacitors electrically arranged in parallel; and/or the configurable electrical component includes a capacitor connected in parallel to a switch to provide a switchable capacitor, and a plurality of switchable capacitors electrically arranged in series.

In yet still further particular, but non-limiting, forms: a further configurable electrical component provides a decoupling output capacitor; the vacuum tube is part of a vacuum tube gain stage; the vacuum tube gain stage is connected via a multiplexer switch to one of a plurality of passive networks; the vacuum tube gain stage is connected to a passive output circuit provided with a further configurable electrical component; the vacuum tube is part of a tone control circuit; the vacuum tube is part of a phase inverter circuit; the vacuum tube is part of a power amplifier; and/or the vacuum tube is part of a power supply circuit.

Optionally, the bypass switch is a relay switch, a photocell switch, a light dependent resistor switch, a solid-state switch, or an opto-triacs switch. Optionally, at least one of the one or more variable resistors is a potentiometer or a digital programmable potentiometer. Preferably, the configurable electrical component includes one or more switches.

In yet still further particular, but non-limiting, forms: a state of the switches is controlled by at least one processor; the state of the switches is stored in one or more registers; the one or more registers are part of a readable/writable memory device; and/or selection of a new amplifier circuit results in the at least one processor causing the state of at least some of the switches to change.

In accordance with other optional aspects: instructions to the at least one processor are provided from or using one or more hardware storage devices; instructions to the at least one processor are provided from or using an external device or network in communication with the amplifier; instructions to the at least one processor are provided from or using a remote information source; and/or instructions to the at least one processor are provided from or using a user interface of the amplifier.

### BRIEF DESCRIPTION OF FIGURES

Example embodiments should become apparent from the following description, which is given by way of example only, of at least one preferred but non-limiting embodiment, described in connection with the accompanying figures.

FIG. 1 (prior art) is a block diagram of a typical modern vacuum tube guitar amplifier.

FIG. 2 is a block diagram of an example embodiment of an amplifier according to one aspect the present invention.

FIG. 3 (prior art) is a block diagram of a known type of circuit for a preamplifier channel.

FIG. 4 (prior art) is a block diagram of another known type of circuit for a preamplifier channel.

FIG. 5 (prior art) is a block diagram of another known type of circuit for switching between different preamplifier channels.

FIG. 6 (prior art) is a block diagram of another known type of circuit for switching between different preamplifier channels, featuring less redundancy than the circuit in FIG. 5.

FIG. 7 (prior art) is a block diagram of another known type of circuit for switching between different preamplifier channels, featuring less redundancy than the circuits in FIG. 5 and FIG. 6.

FIG. 8 is a block diagram which shows an example embodiment of a preamplifier circuit according to one aspect of the present invention.

FIG. 9 is a representation of a single vacuum tube gain stage with configurable components.

FIG. 10 shows example arrangements for adding components in parallel using switches to achieve a desired overall value. Resistors and capacitors are represented in the diagram, but the same method can be applied to inductors or other electronic components.

FIG. 11 shows example arrangements for adding components in series using switches to achieve a desired overall value. Resistors and capacitors are represented in the diagram, but the same method can be applied to inductors or other electronic components.

FIG. 12 is a block diagram of an example triode gain stage from a vacuum tube preamplifier, where the anode and cathode resistors and capacitors, along with the output decoupling capacitor are configurable, for example using the arrangements illustrated in FIG. 10 and/or FIG. 11. This example embodiment can also utilise switches configured as a multiplexer to choose from a variety of output filter networks.

FIG. 13 is a block diagram of another example implementation of a triode gain stage from a vacuum tube preamplifier, where the anode and cathode resistors and capacitors, along with the output decoupling capacitor are configurable, for example using the arrangements illustrated in FIG. 10 and/or FIG. 11. This example embodiment uses one configurable passive output circuit.

FIG. 14 is a representation of an example passive tone control circuit. The tone control performance can be adjusted by switching the values of the resistors and capacitors, for example using the arrangements illustrated in FIG. 10 and/or FIG. 11.

FIG. 15 is a representation of an example phase inverter circuit used in push-pull vacuum tube amplifiers. In a preferred embodiment, the various values of the resistors and capacitors are configurable, for example using the arrangements illustrated in FIG. 10 and/or FIG. 11.

FIG. 16 is a representation of an example push-pull power amplifier. In a preferred embodiment, the various values of the resistors and capacitors are configurable, for example using the arrangements illustrated in FIG. 10 and/or FIG. 11. Besides this, power tube dependant values for primary winding tap, operating voltages, and cathode resistor can be set as ‘global’ parameters.

FIG. 17 is a representation of an example power supply circuit for an amplifier.

FIG. 18 is a representation of an example digital control system for an amplifier.

### PREFERRED EMBODIMENTS

The following modes, given by way of example only, are described in order to provide a more precise understanding of the subject matter of a preferred embodiment or embodiments. In the figures, incorporated to illustrate features of an example embodiment, like reference numerals are used to identify like parts throughout the figures.

Embodiments of the present invention allow improved flexibility, programmability and/or updatability of amplifiers, for example vacuum tube guitar amplifiers. In a preferred form, this is achieved by switching in and out various sections of the amplifier circuit, such as preamplifier gain stages, and optionally also the switching of individual components or groups of components at a circuit level, for example components of a gain stage. Sufficient switching complexity can be provided such that an extremely large number of circuit permutations are available. This configurability can extend to components of the amplifier circuit, including the preamplifier, power amplifier and power supply. Thus, the amplifier can be considered not as a fixed circuit, but rather as a device which has the ability to build or configure circuits as required.

In one form, the is provided an amplifier including a plurality of gain stages, and a bypass switch operable to switch in or out of operation a gain stage of the plurality of gain stages. In a preferred, but non-limiting example, the amplifier is a guitar amplifier. At least one of the plurality of gain stages is preferably a vacuum tube gain stage. The amplifier can also include a plurality of bypass switches each associated with a different gain stage of the plurality of gain stages. This allows each bypass switch, of the plurality of bypass switches, to be operable to switch in or out of operation an associated different gain stage of the plurality of gain stages.

Switching in the amplifier, or amplifier components, is achieved with appropriate switching technology such as, but not limited to, relays, light dependent resistor switching, solid-state switches and/or opto-triacs. Each of these devices or mechanisms has advantages and disadvantages, and can be utilised in areas deemed appropriate by a designer. The state of the switches is stored in one or more registers or other storage devices which are controlled by at least one digital processor. Within the processor's memory is stored the various switch combinations which create a particular circuit. A number of different circuits can be stored in the digital processor's memory, and recalled by the user. When a new circuit is recalled by the user, the digital processor updates the state of the registers, which in turn control the state of the various switches, and thus creates the required circuit. That is, selection of a new amplifier circuit results in at least one processor causing the state of at least some of the switches to change.

Various embodiments may also use digital programmable potentiometers, so that not only the circuit design, but also the potentiometer settings can be controlled by the digital processor. This allows a series of settings to be stored in the processors' memory, and to be recalled when instructed by the user. However, a particular embodiment can also utilise standard potentiometers which are not programmable for a more traditional implementation of this technology. Reference to a digital processor should be read as referring to one or more processors, and can be any type of processing system, which may include a processing unit, memory, an input device, an output device, a bus or group of buses, etc. An interface may also be provided for coupling the processing system to one or more peripheral devices, for example a PC card. As part of the amplifier, or the processing system itself, at least one storage device can be provided which stores a database. The memory can be any form of memory device, for example solid state storage devices, magnetic devices, etc. The processor could include more than one distinct processing device, for example to handle different functions within a processing system.

The updatability of various embodiments can be achieved through a number of implementations or methods. One example implementation includes using interpretable instructions from one or more hardware storage devices, such as a removable ROM or EEPROM device, plug-in card or daughter-board. Thus, when the one or more hardware storage devices, such as a ROM or EEPROM device, is interchanged with another, the available circuits are also changed. Another implementation involves updating of the circuit design instructions from an external device or network. This can be achieved via a suitable communication protocol over MIDI, USB, Ethernet or other suitable connection. A further implementation involves localised updating of the circuit design instructions via a suitable user interface on the amplifier itself.

Thus, in one form instructions for changing circuit configurations can be obtained from a remote information source or terminal, such as a server. The exchange of information (i.e., the request and/or receipt of information or data) between the amplifier and a remote information source, or other terminals, can be facilitated by a communication means, such as a network. The communication means can be realised by physical cables, electromagnetic signals, for example radio-frequency signals or infra-red signals, optical fibre cables, satellite links or any other such medium or combination thereof connected to a network infrastructure. The network itself may take a variety of forms, for example it may be a computer network, telecommunications network, data communications network, Local Area Network (LAN), Wide Area Network (WAN), wireless network, Intranetwork, the Internet or developments thereof.

Besides the specific circuit design parameters, example embodiments also include global circuit-independent parameters, such as the type of power vacuum tube installed in the amplifier. This is used to set up appropriate operating conditions for the particular type of power vacuum tube, such as setting the correct load impedance via taps on the primary winding of the output transformer, setting the correct maximum plate and screen supply voltages, and setting the correct cathode resistor value for cathode-biased operating mode. The design also can be extended to include multiple pairs of power vacuum tubes, each pair being a different type. An appropriate cathode resistor value is chosen for each pair individually for cathode biased operation. In addition to this, the maximum plate and screen supply voltages are set by the digital processor such that the maximum ratings of any pair of tubes is not exceeded.

Despite the relatively large number of vacuum tube amplifiers available for the electric guitar, the vast majority employ relatively similar building blocks, including:
1) Preamplifier: a typical preamplifier consists of one or more low power preamplifier tubes, often triodes. These preamplifier tube stages are connected via passive circuitry and potentiometers which are used to adjust the characteristics of the preamplifier. They often include controls for pre-volume, tone and post-volume. The exact position of these controls in the signal chain can vary.
2) Power amplifier: most guitar amplifiers utilise larger tubes, often pentodes or tetrodes in push-pull configuration, coupled to the speaker through an output transformer. The signals to drive the two phases of the power tubes are generated by a phase inverter. Often, negative feedback is employed from the secondary of the output transformer to an input of the phase inverter in order to regulate the frequency response and dynamic behaviour of the power amplifier. Basic controls to adjust the frequency selective content of the negative feedback, or to add further filtering for the audio signal are also common in the power amplifier circuit.
3) Power supply: to provide a power source for the preamplifier and power amplifier, comprising capacitor banks, inductive chokes, resistors and solid state or vacuum tube rectifiers, as well as other power requirement for the amplifier, such as heater and bias supplies. Some power supplies also include various methods of regulations involving more complex active circuitry.
4) Ancillary circuitry: these include components such as effects loops between the preamplifier and power amplifier, as well as switching logic, etc.

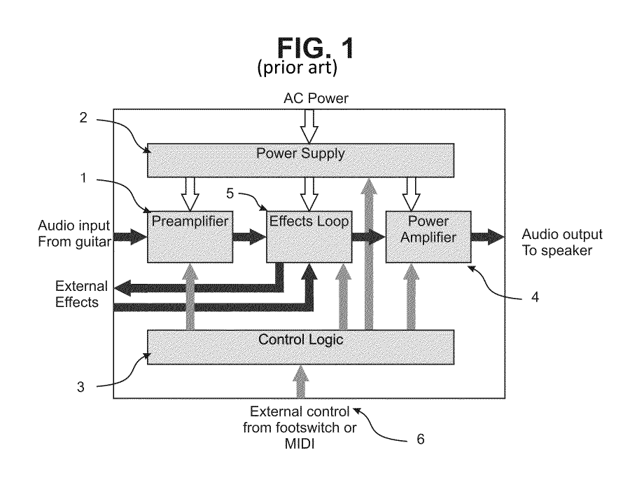

FIG. 1 is a block diagram of a typical modern vacuum tube guitar amplifier. FIG. 1 shows the connection and interplay between the various blocks of the amplifier. The guitar signal, or signal from some other instrument or device, is connected to the input of the preamplifier (1) where the audio signal is processed. The output of the preamplifier (1) is sent to the effects loop circuits (5), which may send the audio signal out of the amplifier to be further processed by an external effects unit(s). After the effects loop (5), the audio signal is sent to the power amplifier (4) which drives the speakers. These audio blocks are all powered by the power supply (2). The switching and configuration of each of these sections is controlled by some rudimentary control logic (3) which responds to signals from an external footswitch, front panel controls, or MIDI messages from an external MIDI controller (6).

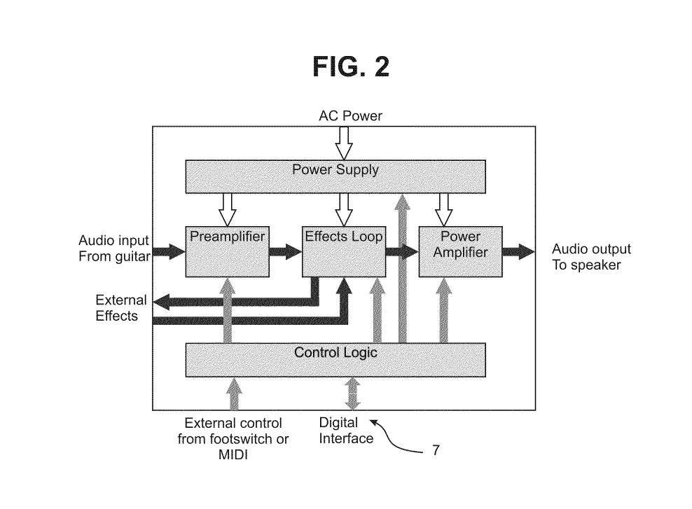

FIG. 2 is a block diagram for an example embodiment of an amplifier according to the present invention. As can be seen, the amplifier architecture illustrated in FIG. 2 has some similarity to a typical modern vacuum tube guitar amplifier architecture as illustrated in FIG. 1. However, besides differences in component structure such as at the control logic, preamplifier, effects loop or power amplifier, there are at least two significant differences:
1) The control signals from the control logic are a lot more detailed, and include signals for setting circuit level component values for each of the main blocks as opposed to simple switching.
2) The amplifier preferably includes a digital interface (7), so that the details of the control signals can be reprogrammed, allowing the amplifier's circuitry to be configured in an entirely different way.

Turning to the various amplifier components or blocks, and starting with the preamplifier, the current state of guitar preamplifiers is firstly discussed. A typical modern guitar preamplifier includes a number of vacuum tube gain stages (typically triodes), with at least one inter-stage gain control. There is usually also a passive tone control, and in many cases, an output volume control.

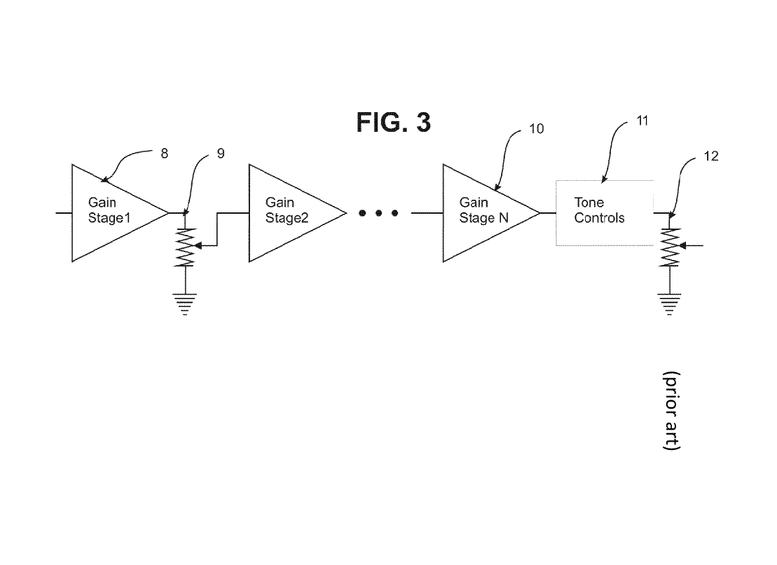

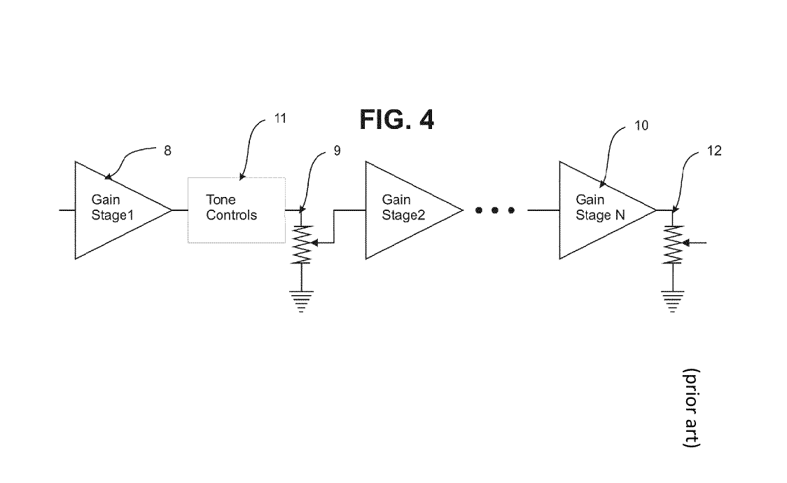

There are various topologies for vacuum tube preamplifier. One of the main defining features of these topologies is the location of the tone controls. The two most common topologies are those which include the tone controls after the last vacuum tube gain stage (as illustrated in FIG. 3), and those which include the tone controls immediately after the first vacuum tube gain stage (as illustrated in FIG. 4).

FIG. 3 depicts an N gain stage vacuum tube preamplifier with a ‘post-gain’ tone control position. The guitar signal enters the first gain stage (8), then is passed to some type of gain level control (9). The audio signal is further amplified through N−1 vacuum tube gain stages (where the last gain stage is often a unity-gain circuit known as a cathode follower). The output of the last gain stage (10) is connected to the tone controls (11), and finally to the final preamplifier output volume control (12).

FIG. 4 depicts an N gain stage vacuum tube preamplifier with a ‘pre-gain’ tone control position. The guitar signal enters the first gain stage (8), then is passed to tone controls (11) whose output is connected to some type of gain level control (9). The audio signal is further amplified through N−1 vacuum tube gain stages. The output of the last gain stage (10) is connected to the output volume control (12).

The vast majority of modern guitar amplifier circuits can be classified as being one of these two topologies. The typical number of gain stages can range from 2 to 6. Whilst these topologies do not exhaust all the current preamplifier designs, they do represent the vast majority of them.

As already mentioned, a modern guitar amplifier often contains multiple ‘channels’. Each channel will have a different preamplifier design with independent controls such that the guitarist may adjust the sound of each channel using control potentiometers and some basic switches, and then foot-switch between these channels to access different sounds. There are a few ways to achieve this in current amplifier designs.

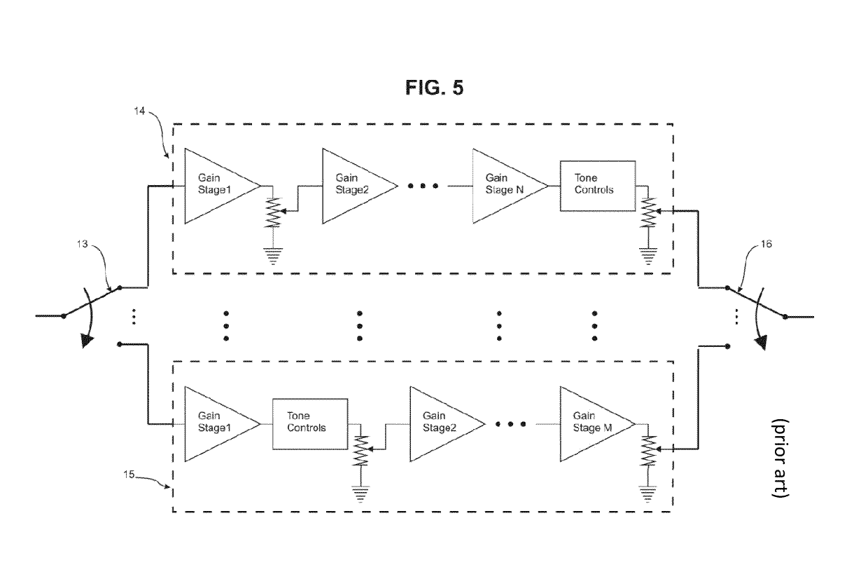

The first of these approaches is depicted in FIG. 5. Here an input multiplexer switch (13) sends the input guitar signal to one of the preamplifier channels (14, 15). Each channel (14, 15) consists of a completely independent set of vacuum tube gain stages, gain, tone and volume controls. An output multiplexer (16) selects the output from the appropriate preamplifier channel (14, 15). This design, although simple, exhibits much redundancy.

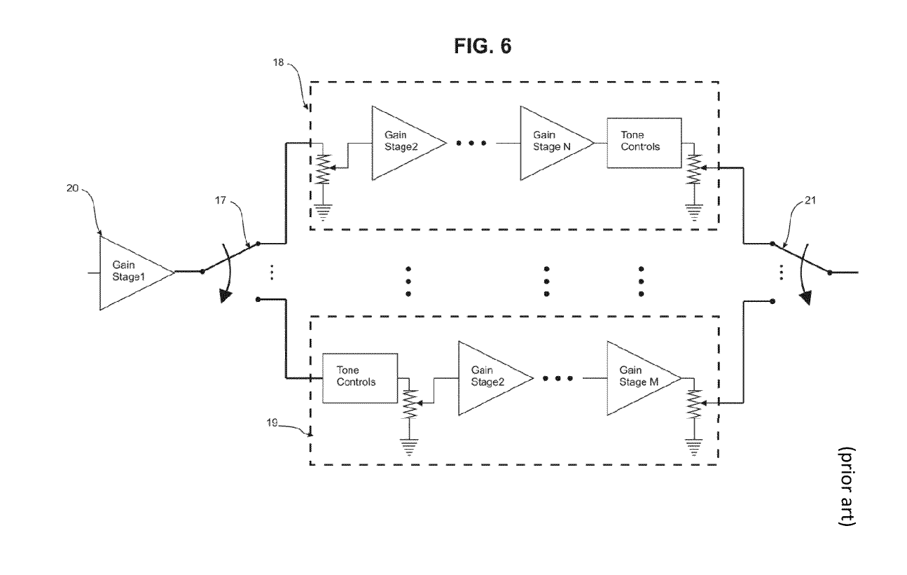

FIG. 6 shows a multi-channel preamplifier with less redundancy. Here, the audio signal is connected to an input gain stage (20), which is then connected to an input multiplexer switch (17) to route the audio signal to the appropriate channel (18, 19). The output of these channels (18, 19) is then selected by the output multiplexer switch (21). In this way, the number of vacuum tubes can be reduced. For example, in an M channel preamplifier design, the number of vacuum tube stages would be reduced by M−1 compared to the circuit in FIG. 5.

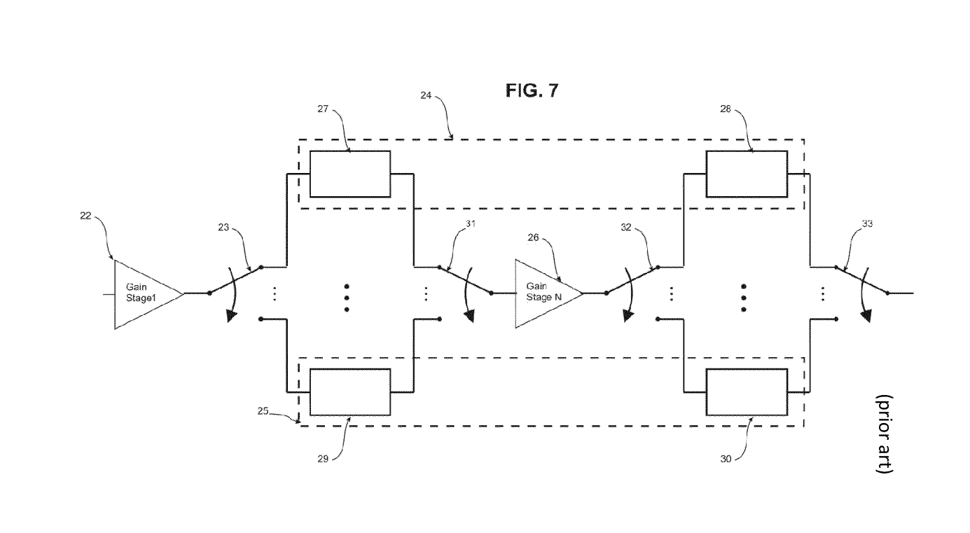

Extending this approach further, FIG. 7 shows a multi-channel preamplifier with less redundancy than those shown in FIG. 5 and FIG. 6. In this implementation, the redundancy is minimised by utilising as many ‘common’ gain stages as possible, and by increasing the switching complexity. In this implementation, the audio signal is connected to an input gain stage (22), which is then connected to an input multiplexer (23) to route the audio signal to the appropriate channel (24, 25). Each channel contains unique circuitry (27, 29), which may themselves contain further gain stages. The output of these stages is selected via a switching multiplexer (31), which then sends the audio signal to further common gain stage(s) (26). An output multiplexer (32) then sends the output of the last gain stage to the passive output controls (28, 30). The appropriate output controls are then selected via a switching multiplexer (33).

This is the limit of complexity of the current available preamplifier designs. It can be seen that despite the switching complexity, it is not possible for any channel in the preamplifier to change its topology. There is also a practical limit on the different number of circuits which can be included in current preamplifier design.

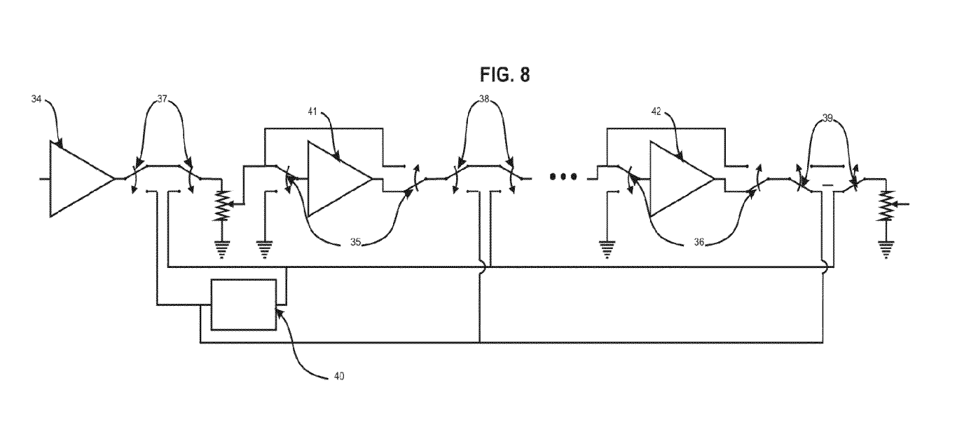

In one aspect, the inventor has developed new preamplifier channel topology. FIG. 8 is a block diagram of an example embodiment for a preamplifier. This embodiment includes a number of vacuum tube gain stages (34, 41, 42), where each of these gain stages, except normally the first gain stage (34), which is preferred but optional, can be bypassed with a double-pole-double-throw (DPDT), or equivalent, switching mechanism (35, 36) (i.e. “bypass switch”). The required switching can be realised using a variety of switching mechanisms, such as relay, photocell or solid-state switching. The specific number of gain stages and associated bypass switches can be varied as desired. Preferably, the output of each vacuum tube gain stage is also connected to a tone controls bypass switch (38), such as a DPDT switching mechanism or equivalent, which can route the audio signal to the tone controls (40) or allow the audio signal to bypass the tone controls (40). The position of the bypass switches should be controlled such that the tone controls (40) are only inserted into one part of the preamplifier circuit, otherwise a section of the preamplifier will be short circuited. For example, as shown in the FIG. 8, when tone controls switch (39) is in the on position, tone controls switch (37) and tone controls bypass switch (38) should be in the off position.

In an example practical realisation of this circuit, there may be total number of 6 vacuum tube gain stages, all of which would contain unique circuitry, and hence would process the audio signal in a unique way. These 6 gain stages would require 5 bypass switches to ‘switch on’ the last 5 gain stages, as well as 6 bypass switches for setting the position of the tone controls. Overall, this creates 120 useable permutations of preamplifier topology. This in itself is a huge leap in flexibility when compared to the current available preamplifier designs. It should be made clear that any number of vacuum tube gain stages could be used, for example 2, 3, 4, 5, 6, 7, 8, 9, 10 or more, which are associated with bypass switches.

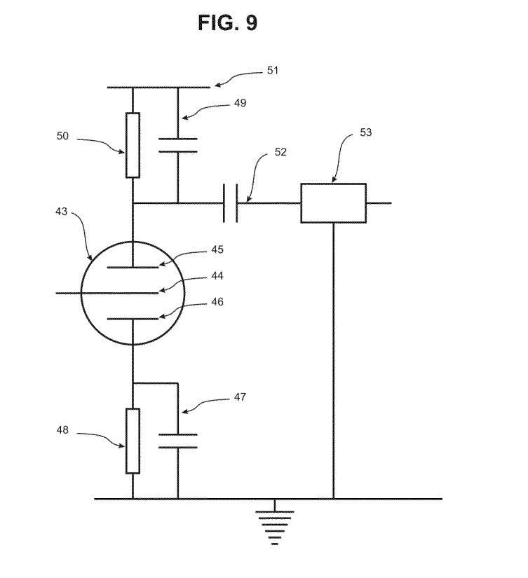

The next level of amplifier, for example preamplifier, configurability is at circuit level. First, consider a vacuum tube preamplifier gain stage, as shown in FIG. 9. A typical vacuum tube preamplifier gain stage topology is illustrated except that one or more components are now configurable. The gain stage includes a single triode vacuum tube (43) with a control grid (44), an anode or plate (45) and a cathode (46). The values of the cathode resistor (48) and cathode capacitor (47) as well as the anode resistor (50) and capacitor (49), along with the supply voltage connected to the anode components (51) determine the main characteristics of this gain stage, including bandpass gain and overall frequency response. Besides this, the value of the output capacitor (52), and the details of the output passive network (53) further define the performance of this gain stage. Previously, the values of these components are chosen during the design phase in order to achieve a particular result, and are thus fixed values.

In another example aspect of the new preamplifier, as opposed to utilising fixed values for gain stage components, the preamplifier includes one or more configurable electrical components, which may be a group of switchable components for at least some, and optionally all, resistors, capacitors, and if included inductors, in the gain stage circuit shown in FIG. 9.

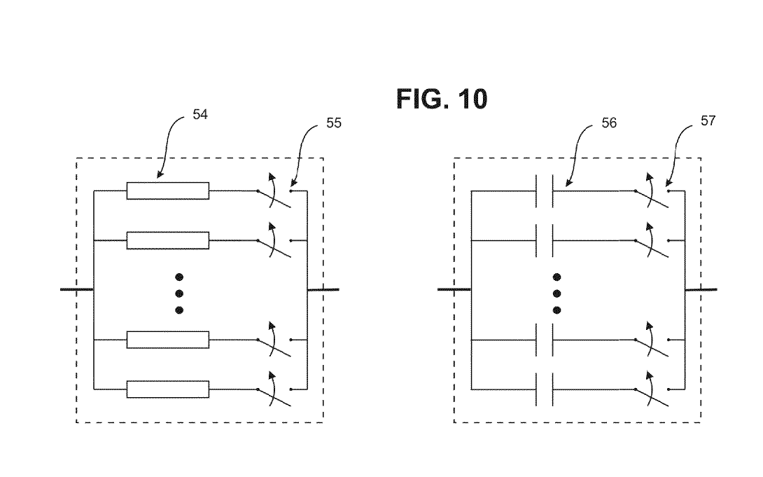

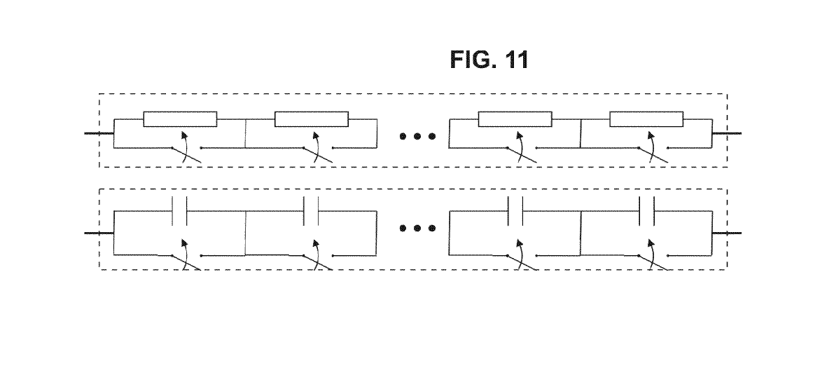

FIG. 10 shows example suitable arrangements or methods for providing configurable electrical components, by switching the components in parallel, allowing not only single resistors (54) and capacitors (56) to be used in circuit by turning on/off the appropriate switches (55, 57), but by turning on/off multiple switches, multiple resistors and capacitors can be used in circuit to fine-tune the required final value. FIG. 11 shows alternate example arrangements or methods to achieve the same or similar results, by switching resistors and/or capacitors in series. It should be noted these arrangements can also apply to inductors or other electrical components if used.

These arrangements or methods can be used to replace the fixed anode and cathode resistors (50, 48) and the fixed anode and cathode capacitors (49, 47), as well as the output capacitor (52) with switchable or configurable networks of components as shown in FIG. 10 or FIG. 11. In this way, by controlling the state of switches, such as switches (55, 57) an extremely large variation of circuits can be configured or built for a gain stage.

This methodology can also be applied to other active preamplifier stages, including, but not limited to low power pentode preamplifier stages, AC and DC cathode followers, cascode configured stages and mu-followers. In fact, various embodiments can include all of these various types of configurable active gain stages which may be included in a particular preamplifier configuration or bypassed.

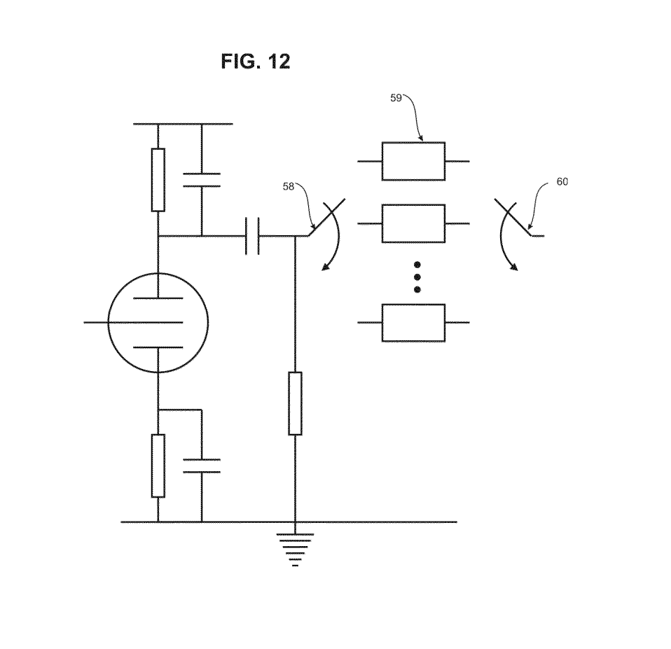

For the output passive network (53), there are a few options for the implementation of a switchable network. The first of these is depicted in FIG. 12. In this figure, the output of the vacuum tube is connected to an audio multiplexer switch (58) which chooses between a series of fixed passive networks (59). The appropriate passive network output is then selected by an output audio multiplexer switch (60).

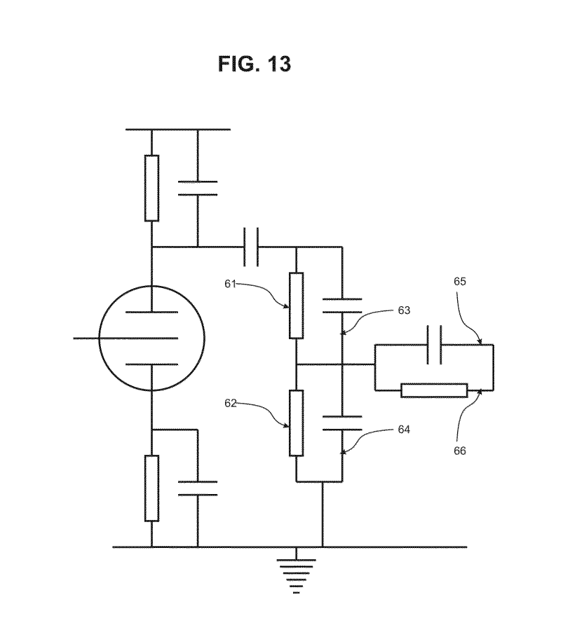

FIG. 13 shows an alternate implementation. Instead of choosing between a series of output networks, this implementation features a passive network comprising a group of resistors, for example three resistors (61, 62, 66) as illustrated, and a group of capacitors, for example three capacitors (63, 64, 65) as illustrated. Instead of fixed values, one or more of the resistors and one or more of the capacitors can be provided not as single devices but using an arrangement such as those shown in FIG. 10 or FIG. 11. By controlling the state of the various switches, a large number of passive output networks could be configured.

It should also be noted at this stage that this is the most typical configuration for a triode vacuum tube gain stage. There are also other configurations, such as AC and DC cathode followers, as well as gain stages with localised negative feedback. All of these could be implemented as configurable stages using the same or similar arrangements or methodology as described above.

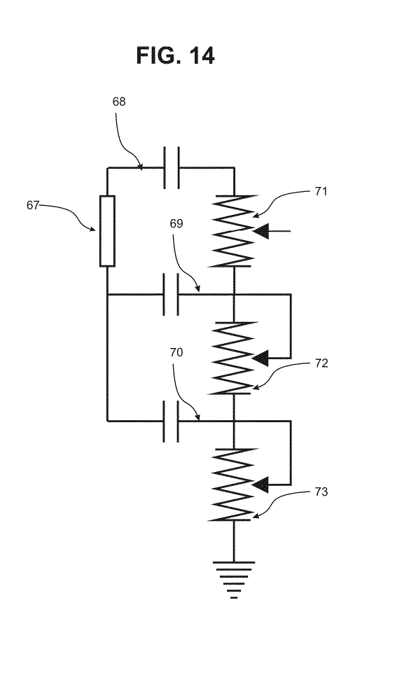

The next main configurable detail of the preamplifier circuit is the tone controls. An example passive tone control circuit is shown in FIG. 14, which is a typical type of tone control topology found in guitar preamplifiers. The tone control circuit includes a ‘slope’ resistor (67), the treble capacitor (68), bass capacitor (69) and midrange capacitor (70).

However, the new tone controls circuit can be provided by including a custom configuration ability by switching the value of the electrical components using the example arrangements or methods shown in FIG. 10 or FIG. 11. The treble potentiometer (71), bass potentiometer (72) and midrange potentiometer (73) can be traditional analog potentiometers, or digital programmable potentiometers. Besides this, various passive input and output circuits can be switched in and out in order to further tailor the response of the tone controls. Finally, the architecture of the tone controls can be switched to implement other designs, including, but not limited to Baxandall, simple high and low cut, as well as notch filters. Alternatively, these various designs can be implemented in parallel, and the preamplifier can be configured to choose one of these implementations. All of this switching can be realised using appropriate switching mechanisms, such as relay, photocell or solid-state switching.

As can be seen, an extremely large number of component permutations can create a virtually limitless number of preamplifier circuit variations. This allows various embodiments to not only approximate known preamplifier circuits, but also to create new circuits without the need to physically swap any of the analog circuitry of the preamplifier. All that is required is to set the state of each of the switches, which can be achieved with digital processor circuitry.

The next area of interest is the power amplifier. There are three typical configurations for the power amplifier circuit, namely push-pull fixed bias, push-pull cathode biased and single ended class A. The push-pull configuration includes one or more pairs of power vacuum tubes, where each vacuum tube in the pair is driven by opposite phase signal. This requires a phase inverter circuit to produce a 180 degree out of phase audio signal in order to drive two opposite phases of the push pull configuration. The most typical type of phase inverter is commonly referred to as an AC coupled long-tail circuit. Other configurations include the DC coupled long-tail pair, the cathodyne phase inverter and the paraphase inverter.

Various aspects of the power amplifier are now considered, namely the phase inverter, and power tubes with output transformer.

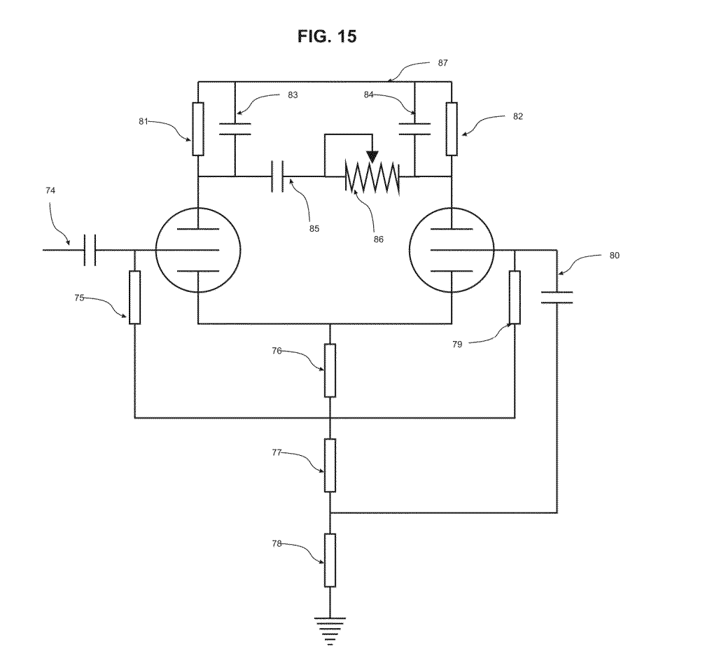

FIG. 15 shows a known type of phase inverter topology, which is the triode based differential amplifiers often referred to as an AC coupled long-tail pair. In general, the values of the components are chosen to achieve equal gain for both phases, with sufficient signal swing to drive the power tubes to full power. Besides this, different phase inverter designs may also shape the frequency response of the phase inverter by using appropriate values for the input coupling capacitor (74), the second grid capacitor (80), the anode capacitors (83, 84), and the common anode capacitor (85). Besides this, some phase inverter designs also include a variable resistor (86) so that an adjustable amount of high frequencies can be cut from the phase inverter.

In various embodiments, the values of all of these capacitors, along with the grid resistors (75, 79), the bias networks (76, 77, 78) as well as the anode resistors (81, 82) could be adjusted with switching arrangements, for example as shown FIG. 10 or FIG. 11. In practice the number of permutations need not be as high as for the preamplifier gain stages, since the function of the phase inverter is fairly fixed, and need not be as ‘variable’. However, provision is made for a reasonable variability.

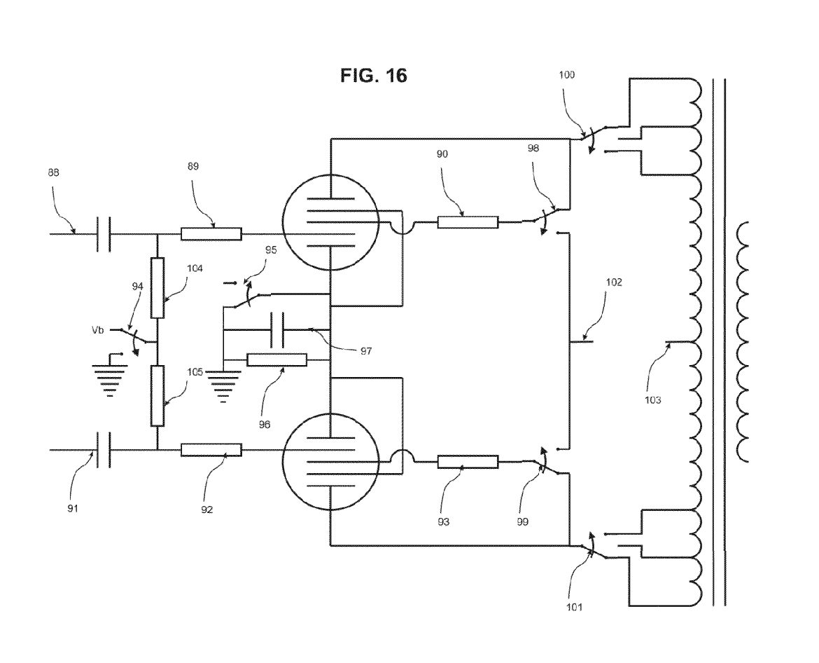

FIG. 16 shows an example power amplifier which includes a pair of power vacuum tubes in push-pull configuration. By applying a similar methodology to the power amplifier, it is possible to change the value of components such as the input coupling capacitors (88, 91), and grid stop resistors (80, 92). Besides this, the power amplifier can be switched to configure into various configurations. Switches 94 and 95 work in tandem to switch the amplifier from fixed bias to cathode biased operation. In fixed bias operation, switch 94 connects the grid bias resistors (104, 105) to a negative bias voltage Vb, while switch 95 short circuits the cathode resistor (96) and capacitor (97), thus connecting the power tube cathodes directly to ground. In cathode biased operation, the grid bias resistors (104, 105) are connected to ground via switch 94, while switch 95 is switched to the open circuit position, thus allowing the cathode current to flow through the cathode resistor (96) and capacitor (97). Finally, switches 98 and 99 can connect the screens of the power tubes to the DC screen supply (109) or to their respective plates (100, 101) for quasi-triode performance.

Besides these options, there are global parameters which are dependent of the type of power tube used. In another embodiment, the power amplifier can use a wide variety of power tubes. Due to this, circuit parameters such as the correct screen supply voltage (102) and anode supply voltage (103), as well as an appropriate value for the cathode resistor (96) must be chosen, so as to provide suitable operating conditions for the power tubes. Besides this, switches 100 and 101 are also used to connect the anodes of the power tubes to an appropriate tap on the primary of the audio output transformer in order to produce an appropriate load impedance for the particular type of power tubes being used.

The embodiments discussed above can also be extended to simpler single ended class-A designs.

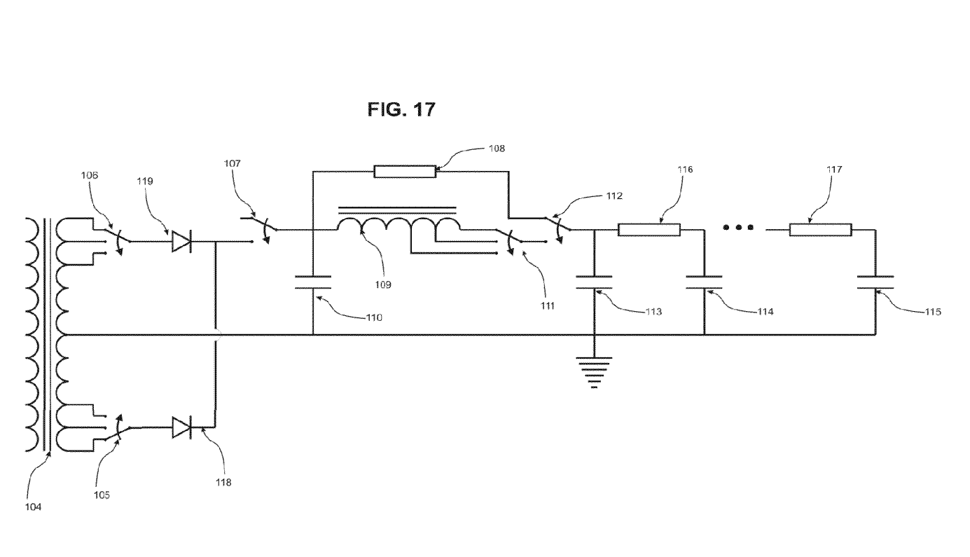

A further configurable section of the amplifier is the power supply. Unlike a hi-fi amplifier the response of the power supply is an integral part of the tactile ‘feel’ of the amplifier, and hence an important section for configurability. FIG. 17 is a representation of an example power supply. The secondary winding of the power transformer (104) contains multiple taps to produce multiple output voltages. Switches 105 and 106 are used to select the appropriate operating voltage for the power tubes. The diodes represented in this embodiment are silicon diodes (118, 119), but it is also possible to use other diodes such as vacuum tube diodes. Switch 107 is the standby switch for the disabling the high voltage supply. This happens either when the user activates the standby mode of the amplifier, or when the digital controlled disables the high voltage in order to reconfigure the power supply. This reduces the chance of damage occurring to the inductive elements of the amplifier such as the choke (109) and the output transformer, or switching devices.

The values of each of the power supply capacitors (110, 113, 114, 115) can be configured using a switching arrangement, such as the switching arrangements in FIG. 10 or FIG. 11. Capacitor 110 is the main power supply capacitor which supplies the power tube anodes, connected to the centre of the output transformer primary (103). Capacitor 113 is the capacitor for the screen supply (102). All subsequent capacitors (114, 115) are for the preamplifier power supply. Besides these capacitor values, the values of the preamplifier supply resistors can also be configured, for example using the arrangements shown in FIG. 10 or FIG. 11.

For the screen supply, there are two main methods of filtering, namely a filter using a resistor and a capacitor, or an inductive choke and a capacitor. In a preferred embodiment there is included both a resistor (108) and an inductive choke (109), and a switch to choose between them. The value of the resistor 108 is also software selectable. Besides this, the filter choke features multiple output taps corresponding to different inductance values, which can be selected via switch 111 to produce different amounts of filtering.

Having now covered areas of configurability of the analog circuit, we now turn our attention to the method of control and update of the circuit using the digital processor.

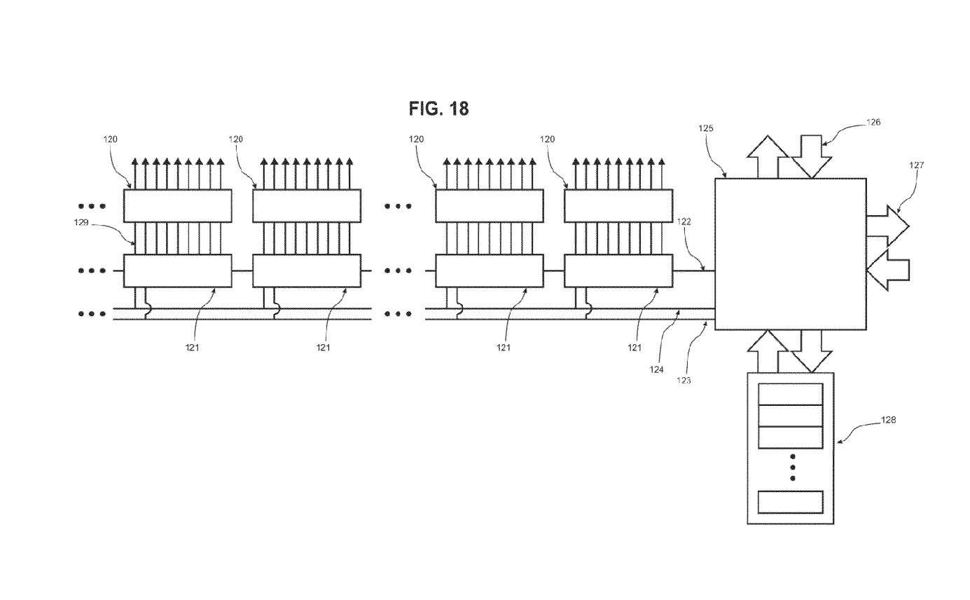

FIG. 18 is a representation of example digital control circuitry, including digital processor (125) connected to a readable/writable memory device (128), such as an EEPROM memory module. The memory device (which may be internal to the digital processor) contains N addresses, where N is the number of different circuits which can be configured in the amplifier, chosen at design time. The digital processor also has an I/O interface to the amplifier's control panel (126) which allows the user to choose an amplifier circuit, as well as configure the digital potentiometers, if the implementation uses these. This embodiment also allows the user to make changes to the amplifier circuit. At the same time the digital processor also includes another I/O interface for communication to external devices (127).

When a signal is received to reconfigure the amplifier circuit, or part thereof, to configuration ‘M’ via the user interface (126) or the digital I/O (127), the digital processor reads the switch settings from memory (128) in memory location ‘M’. It then sends the data out to the serial shift registers (121) using the data (122), serial clock (123) and shift enable (124) lines. After the switch states have been shifted through the entire register, the data is loaded into the output of the resisters (129), which drive the switch drivers (120), thus setting the state of all the switches, and configuring a new circuit.

The digital control system also contains a provision to upload the circuit data from memory (128) via the digital I/O (127) for storage on an external device, or external editing of the circuit data. Similarly, the contents of the memory (128) can be updated by the digital processor (125) via the control panel user interface (126) or digital I/O (127). Another embodiment could utilise ROM instead of EEPROM, so that the circuits stored in memory could not be updated. Updating of the circuits would involve replacing the ROM.

Optional embodiments of the present invention may also be said to broadly consist in the parts, elements and features referred to or indicated herein, individually or collectively, in any or all combinations of two or more of the parts, elements or features, and wherein specific integers are mentioned herein which have known equivalents in the art to which the invention relates, such known equivalents are deemed to be incorporated herein as if individually set forth.

Although a preferred embodiment has been described in detail, it should be understood that many modifications, changes, substitutions or alterations will be apparent to those skilled in the art without departing from the scope of the present invention.

1-13. (canceled)

14. A guitar amplifier, comprising:
a vacuum tube including an anode and a cathode, wherein the vacuum tube is part of a vacuum tube gain stage; and
a configurable electrical component connected to the vacuum tube, wherein the configurable electrical component is a configurable resistance component, a configurable capacitance component and/or a configurable inductance component.

15. (canceled)

16. The amplifier of claim 14, wherein the configurable electrical component includes one or more variable resistors and/or one or more variable capacitors.

17. The amplifier of claim 14, wherein the configurable electrical component includes a resistor or capacitor connected in series to a switch to provide a switchable resistor or capacitor, and a plurality of switchable resistors or capacitors electrically arranged in parallel.

18. The amplifier of claim 14, wherein the configurable electrical component includes a resistor or capacitor connected in parallel to a switch to provide a switchable resistor or capacitor, and a plurality of switchable resistors or capacitors electrically arranged in series.

19-21. (canceled)

22. The amplifier of claim 14, including a further configurable electrical component providing a decoupling output capacitor.

23. (canceled)

24. The amplifier of claim 14, wherein the vacuum tube gain stage is connected via a multiplexer switch to one of a plurality of passive networks.

25. The amplifier of claim 14, wherein the vacuum tube gain stage is connected to a passive output circuit provided with a further configurable electrical component.

26. The amplifier of claim 14, wherein the vacuum tube is part of a tone control circuit.

27. The amplifier of claim 14, wherein the vacuum tube is part of a phase inverter circuit.

28. The amplifier of claim 14, wherein the vacuum tube is part of a power amplifier.

29. The amplifier of claim 14, wherein the vacuum tube is part of a power supply circuit.

30. (canceled)

31. The amplifier of claim 14, wherein the configurable electrical component includes one or more switches.

32. (canceled)

33. The amplifier of claim 31, wherein a state of the one or more switches is controlled by at least one processor.

34. The amplifier of claim 33, wherein the state is stored in one or more registers.

35. The amplifier of claim 34, wherein the one or more registers are part of a readable/writable memory device.

36. The amplifier of claim 33, wherein selection of a new amplifier circuit results in the at least one processor causing the state to change.

37. The amplifier of claim 36, wherein instructions to the at least one processor are provided from or using one or more hardware storage devices.

38. The amplifier of claim 36, wherein instructions to the at least one processor are provided from or using an external device or network in communication with the amplifier.

39. The amplifier of claim 36, wherein instructions to the at least one processor are provided from or using a remote information source.

40. The amplifier of claim 36, wherein instructions to the at least one processor are provided from or using a user interface of the amplifier.
